(19) United States
(12) Patent Application Publication
(10) Pub. No.: US 2024/0263304 A1
(43) Pub. Date: Aug. 8, 2024

(54) SUBSTRATE PROCESSING APPARATUS

(71) Applicant: ASM IP Holding B.V., Almere (NL)

(72) Inventors: Seung Wook Kim, Gyeongsangnam-do (KR); Ju Ill Lee, Cheonan-si (KR); Won Ki Jeong, Cheonan-si (KR); Dong Rak Jung, Hwaseong-si (KR); Hong Hyun Kim, Gyeonggi-do (KR)

(21) Appl. No.: 18/638,154

(22) Filed: Apr. 17, 2024

Related U.S. Application Data
(62) Division of application No. 16/039,817, filed on Jul. 19, 2018, now Pat. No. 11,993,843.

(30) Foreign Application Priority Data
Aug. 31, 2017 (KR) 10-2017-0111040

(51) Int. Cl. C23C 16/44; C23C 16/455; C23C 16/458; H01J 37/32

(52) U.S. Cl. CPC C23C 16/4411; C23C 16/45565; C23C 16/45572; H01J 37/32522; C23C 16/45551; C23C 16/4586; H01J 37/32082

(57) ABSTRACT

Provided is a cooling device capable of controlling the temperature of an upper portion of a reactor, or more particularly, a gas supply device, for example, a shower head. The cooling device includes a separator configured to uniformly and efficiently cool the gas supply device.

### CROSS-REFERENCE TO RELATED APPLICATION

This application is a divisional of, and claims priority to, U.S. patent application Ser. No. 16/039,817 filed Jul. 19, 2018, entitled “SUBSTRATE PROCESSING APPARATUS,” which claims the benefit of Korean Patent Application No. 10-2017-0111040, filed on Aug. 31, 2017, in the Korean Intellectual Property Office, the disclosures of which are incorporated herein in their entirety by reference.

### BACKGROUND

### 1. Field

One or more embodiments relate to a substrate processing apparatus, and more particularly, to a cooling device capable of controlling the temperature of a gas supply device.

### 2. Description of the Related Art

A substrate processing apparatus, for example, a semiconductor substrate processing apparatus, is heated to a process temperature to facilitate a chemical reaction between reactive gases. For example, a peripheral portion surrounding a substrate, such as a reactor wall, or a reactor cover (for example, a top lid), is heated to a certain temperature. As such, as the entire reactor is heated and a temperature to which the reactor is heated is maintained, a process may be smoothly carried out.

However, the temperature of a particular portion of a reactor may not be controlled in a high-temperature process. In such a case, the temperature balance of the entire reactor may be destroyed, and thus process repeatability may deteriorate. For example, when the temperature of a substrate support is 500° C. or more, the actual temperature of a gas supply device, for example, a shower head, facing the substrate support, may be higher than 250° C., which is higher than a setting temperature of 200° C.

Moreover, when the temperature is not properly controlled, secondary damage may occur, for example, in the form of a safety problem that may occur where a worker is burned due to the high temperature, malfunction due to thermal shock to major parts such as a valve, gauge, etc., a chamber leak due to hardening of a sealing member such as an O-ring, a problem where the quality of a deposited thin film deteriorates due to the introduction of external air, etc.

### SUMMARY

One or more embodiments include a device for controlling the temperature of an upper portion of a reactor, in detail, a gas supply device, for example, a shower head.

One or more embodiments include a cooling device having improved cooling efficiency.

Additional aspects will be set forth in part in the description which follows and, in part, will be apparent from the description, or may be learned by practice of the presented embodiments.

According to one or more embodiments, a cooling device including a first partition, a second partition surrounding the first partition, a third partition surrounding the second partition, and a separator separating a space between the second partition and the third partition into a first area and a second area, and separating a space between the second partition and the first partition into a third area and a fourth area, wherein the separator is configured to connect the first area and the third area with each other and the second area and the fourth area with each other.

The separator may include a body, a first channel, and a second channel, the first area and the third area may be connected to each other by the first channel of the separator, the second area and the fourth area may be connected to each other by the second channel of the separator, and the first channel and the second channel may not meet each other.

The first channel may be in an upper portion of the separator, and the second channel may be in a lower portion of the separator.

The separator may include a body, a first member located in an upper portion of the separator and between the second partition and the third partition, a second member located in the upper portion of the separator and between the first partition and the second partition, a third member located in a lower portion of the separator and between the second partition and the third partition, a fourth member located in the lower portion of the separator and between the first partition and the second partition, a first channel formed by the first member and the second member, and a second channel formed by the third member and the fourth member, wherein the first area and the third area are connected to each other by the first channel, the second area and the fourth area are connected to each other by the second channel, and the first channel and the second channel do not meet each other.

One surface of each of the first member, the second member, the third member, and the fourth member may contact the second partition.

The first member and the third member may contact the third partition, and the second member and the fourth member may contact the first partition.

The first member, the second member, the third member, and the fourth member may have the same height, and the first channel and the second channel each may have a same uniform width.

The cooling device may further include an inlet for introducing a coolant. When the inlet is located between the second partition and the third partition, the separator may enable the coolant flowing in a clockwise direction between the second partition and the third partition to continue to flow in a clockwise direction between the first partition and the second partition, and the separator may enable the coolant flowing in a counterclockwise direction between the second partition and the third partition to continue to flow in a counterclockwise direction between the first partition and the second partition. When the inlet is located between the first partition and the second partition, the separator may enable the coolant flowing in a clockwise direction between the first partition and the second partition to continue to flow in a clockwise direction between the second partition and the third partition, and the separator may enable the coolant flowing in a counterclockwise direction between the first partition and the second partition to continue to flow in a counterclockwise direction between the second partition and the third partition.

The cooling device may further include one or more grooves arranged between the first partition and the second partition or between the second partition and the third partition.

According to one or more embodiments, a cooling device includes at least one inlet, a fluid channel through which a coolant circulates, the coolant being introduced through at least one inlet, a partition separating the fluid channel into a first area and a second area, and a separator penetrating through the partition and extending across the first area and the second area, wherein the at least one inlet introduces the coolant into the first area, two flows of the coolant flowing in different directions are formed in the first area, and the two flows of the coolant flowing in different directions in the first area are introduced into the second area via the separator without colliding or mixing with each other.

The separator may enable the coolant flowing in a clockwise direction in the first area to continue to flow in a clockwise direction in the second area, and the separator may enable the coolant flowing in a counterclockwise direction in the first area to continue to flow in a counterclockwise direction in the second area.

According to one or more embodiments, a cooling device include a first partition, a second partition surrounding the first partition, a third partition surrounding the second partition, and a separator separating a space between the second partition and the third partition into a first area and a second area, and separating a space between the second partition and the first partition into a third area and a fourth area, wherein the separator is configured to connect the first area and the third area with each other.

The separator may include a body and a channel, and the first area and the third area are connected to each other by the channel of the separator.

The separator may include a body, a first member located between the second partition and the third partition, a second member located between the first partition and the second partition, and a channel formed by the first member and the second member, wherein the first area and the third area are connected to each other by the channel.

One surface of each of the first member and the second member may contact the second partition.

The first member may contact the third partition, and the second member may contact the first partition.

The first member and the second member may have a same height, and the channel may have a uniform width.

When a flow direction of the coolant in the first area is a clockwise direction, the separator may enable the coolant flowing in a clockwise direction in the first area to continue to flow in a clockwise direction in the third area. When a flow direction of the coolant in the first area is a counterclockwise direction, the separator may enable the coolant flowing in a counterclockwise direction in the first area to continue to flow in a counterclockwise direction in the third area.

According to one or more embodiments, a gas supply device including a cooling device as described above may be provided.

According to one or more embodiments, a substrate processing apparatus includes a chamber having an inner space surrounded by a top lid and an outer wall, at least one reactor located in the top lid and including a gas supply device, at least one substrate support located on a wall of the chamber and facing the reactor, a reaction space formed between the reactor and the substrate support, and a cooling device provided over the reactor or over the gas supply device.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic top view of a cooling device according to an embodiment;

FIG. 2 is a schematic top view of a cooling device according to another embodiment;

FIG. 3 is a schematic top view of a modified example of the cooling device of FIG. 1;

FIG. 4A is a perspective view of a separator used in the cooling devices of FIGS. 1 and 3, and FIG. 4B illustrates that the separator is provided in a fluid channel;

FIGS. 5A to 5D are perspective views, in different directions, of the separator used in the cooling device of FIG. 2;

FIGS. 6A and 6B are perspective views of the separator used in the cooling device of FIG. 2, showing an arrangement relationship of a body, a first channel, a second channel, and a partition;

FIGS. 7A and 7B are schematic top views of a cooling device according to other embodiments;

FIG. 8A is a perspective view of the separator used in the cooling device of FIGS. 7A and 7B, and FIG. 8B illustrates that the separator of FIGS. 7A and 7B is provided in the fluid channel;

FIGS. 9A and 9B are, respectively, appearance and perspective views of a cooling device according to another embodiment, and FIG. 9C illustrates a coolant flow path in the cooling device;

FIGS. 10A and 10B schematically illustrate a cover of the cooling device of FIG. 9A;

FIG. 11 is a cross-sectional view of the cooling device of FIG. 9A;

FIGS. 12A and 12B are perspective views of the cooling device of FIG. 9A before being covered with a cover;

FIGS. 13A and 13B are schematic top views illustrating various flow directions of a coolant flowing in the cooling device, according to embodiments;

FIGS. 14A and 14B are schematic top views of cooling devices according to other embodiments;

FIGS. 15A and 15B are schematic top views of cooling devices according to other embodiments; and

FIG. 16 is a schematic cross-sectional view of a substrate processing apparatus including the cooling device, according to another embodiment.

### DETAILED DESCRIPTION

Embodiments are provided to further completely explain the present inventive concept to one of ordinary skill in the art to which the present inventive concept pertains. However, the present inventive concept is not limited thereto and it will be understood that various changes in form and details may be made therein without departing from the spirit and scope of the following claims. That is, descriptions on particular structures or functions may be presented merely for explaining embodiments of the present inventive concept.

Terms used in the present specification are used for explaining a specific embodiment, not for limiting the present inventive concept. Thus, the expression of singularity in the present specification includes the expression of plurality unless clearly specified otherwise in context. Also, terms such as “comprise” and/or “comprising” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

In the present specification, terms such as “first” and “second” are used herein merely to describe a variety of members, parts, areas, layers, and/or portions, but the constituent elements are not limited by the terms. It is obvious that the members, parts, areas, layers, and/or portions are not limited by the terms. The terms are used only for the purpose of distinguishing one constituent element from another constituent element. Thus, without departing from the right scope of the present inventive concept, a first member, part, area, layer, or portion may refer to a second member, part, area, layer, or portion.

Hereinafter, the embodiments of the present inventive concept are described in detail with reference to the accompanying drawings. In the drawings, the illustrated shapes may be modified according to, for example, manufacturing technology and/or tolerance. Thus, the embodiment of the present inventive concept may not be construed to be limited to a particular shape of a part described in the present specification and may include a change in the shape generated during manufacturing, for example.

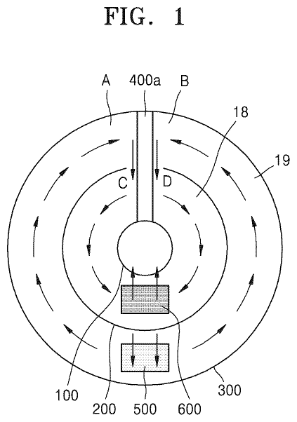

FIG. 1 is a schematic top view of a cooling device according to an embodiment.

Referring to FIG. 1, the cooling device according to the present embodiment may include a first partition 100, a second partition 200 surrounding the first partition 100, a third partition 300 surrounding the second partition 200, a separator 400a, an inlet 500, and an outlet 600.

A fluid channel may be formed by the first partition 100 and the third partition 300. The second partition 200 is provided between the first partition 100 and the third partition 300 to separate the fluid channel into two areas, that is, inner and outer areas 18 and 19. In the exemplified embodiment, an inner area 18 may be formed by the first partition 100 and the second partition 200, and an outer area 19 may be formed by the second partition 200 and the third partition 300.

The inlet 500 may be arranged between the second partition 200 and the third partition 300. The inlet 500 may introduce a coolant between the second partition 200 and the third partition 300, that is, into the outer area 19, and may define two flows of the coolant flowing in different directions in the outer area 19. Since a deposition process is generally sensitive to temperature, temperature irregularity of a gas supply device (not shown) may affect the deposition process. Accordingly, as illustrated in FIG. 1, the inlet 500 may define two flows of the coolant flowing in different directions, for example, a clockwise direction and a counterclockwise direction, in the outer area 19. Accordingly, cooling unbalance between the left side and the right side of the gas supply device may be prevented, and temperature uniformity may be guaranteed.

The separator 400a may be arranged on one surface of the fluid channel to separate a space between the second partition 200 and the third partition 300, that is, the outer area 19, into a first area A and a second area B, and a space between the second partition 200 and the first partition 100, that is, the inner area 18, into a third area C and a fourth area D. In this case, the separation of the outer area 19 into the first area A and the second area B by the separator 400a signifies not that the outer area 19 is completely separated into two independently areas, but that part of the outer area 19 is separated into the first area A and the second area B. In other words, although the second area B of the outer area 19 is separated from the first area A in a part of the cooling device, it may be connected to the first area in other part of the outer area 19. For example, referring to FIG. 1, although the outer area 19 is separated by the separator 400a into the first area A and the second area B in a part of the cooling device (in an upper portion of the drawing), the first area A and the second area B may be connected to each other in other part of the cooling device (in a lower portion of the drawing). As such, throughout the present specification, the expression “separated into two areas” does not signify the separation of a space into two completely independent areas.

In the exemplified embodiment, the separator 400a may be configured to extend between the third partition 300 and the first partition 100 by penetrating through the second partition 200. Accordingly, the separator 400a may separate the outer area 19 into the first area A and the second area B, and the inner area 18 into the third area C and the fourth area D.

The separator 400a may be configured to connect the first area A and the third area C with each other and connect the second area B and the fourth area D with each other. Accordingly, the separator 400a may guide the coolant in the outer area 19 of the fluid channel to flow toward the inner area 18, or the coolant in the inner area 18 of the fluid channel to flow toward the outer area 19. In the exemplified embodiment, the separator 400a may be configured to connect the first area A and the third area C with each other, thereby guiding the coolant in the first area A to flow toward the third area C.

The separator 400a may change a flow direction of the coolant flowing along the fluid channel. For example, as illustrated in FIG. 1, the flow direction of the coolant flowing clockwise in the first area A of the outer area 19 may be changed by the separator 400a to the counterclockwise direction in the third area C of the inner area 18. Likewise, the flow direction of the coolant flowing counterclockwise in the second area B of the outer area 19 may be changed by the separator 400a to the clockwise direction in the fourth area D of the inner area 18.

As such, the separator 400a may guide the two flows of the coolant in the outer area 19 to flow in different directions in the inner area 18. In the exemplified embodiment, the two flows of the coolant flowing in different directions in the outer area 19 (clockwise direction, counterclockwise direction) may also flow in different directions in the inner area 18 (counterclockwise direction, clockwise direction).

The two flows of the coolant flowing in different directions in the outer area 19 may flow in the inner area 18 by the separator 400a without collision or mixing therebetween. In other words, the separator 400a may prevent the two flows of the coolant flowing in different directions in the outer area 19 from colliding with each other. In detail, the coolant flowing in the first area A may flow in the third area C by the separator 400a, not in the second area B or the fourth area D.

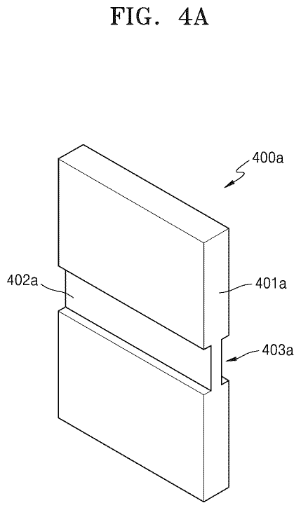

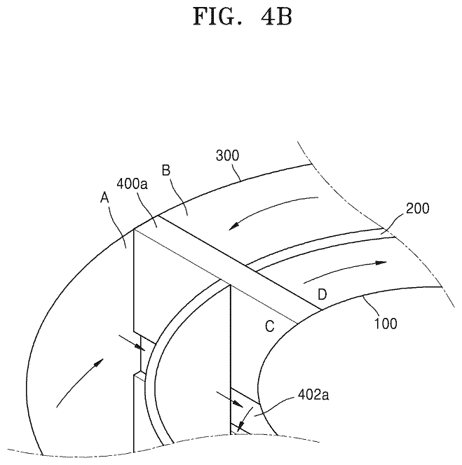

For example, although the separator 400a may have a partition structure, alternatively, the separator 400a may have a structure as illustrated in FIGS. 4A and 4B.

In a selective or additional example, one or more grooves (not shown) may be arranged between the first partition 100 and the second partition 200 and/or between the second partition 200 and the third partition 300. The grooves may define the flow direction of a coolant. Furthermore, the grooves may increase cooling efficiency by increasing a contact area between the coolant and the cooling device.

The coolant flowing in the inner area 18 may be discharged through the outlet 600 arranged between the first partition 100 and the second partition 200.

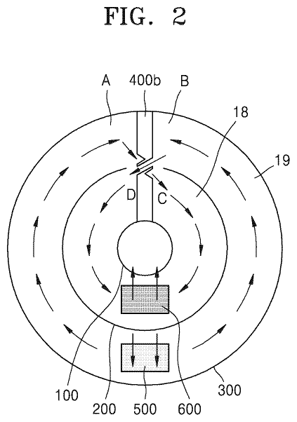

FIG. 2 is a schematic top view of a cooling device according to another embodiment. The cooling device according to the present embodiment may be a modification of the cooling device according to the above-described embodiment. Redundant descriptions between the embodiments may be omitted.

Referring to FIG. 2, the cooling device may include the first partition 100, the second partition 200 surrounding the first partition 100, the third partition 300 surrounding the second partition 200, a separator 400b, the inlet 500, and the outlet 600.

The separator 400b may separate the space between the second partition 200 and the third partition 300 into the first area A and the second area B, and the space between the second partition 200 and the first partition 100 into the third area C and the fourth area D. In the exemplified embodiment, the separator 400b is configured to extend between the third partition 300 and the first partition 100 by penetrating through the second partition 200.

The separator 400b may connect the first area A and the third area C with each other and the second area B and the fourth area D with each other.

Unlike FIG. 1, in which the first area A and the third area C are located at the same side with respect to the separator 400a, in FIG. 2, the first area A and the third area C are located at different sides with respect to the separator 400b, and the second area B and the fourth area D are also located at different sides with respect to the separator 400b.

Due to the above configuration, the separator 400b of FIG. 2, unlike the separator 400a of FIG. 1, may not change the flow direction of the coolant flowing along the fluid channel. For example, as illustrated in FIG. 2, the coolant flowing in the clockwise direction in the outer area 19 continuously flows in the clockwise direction in the inner area 18 by the separator 400b, and the coolant flowing in the counterclockwise direction in the outer area 19 continuously flows in the counterclockwise direction in the inner area 18 by the separator 400b.

In the cooling device of FIG. 1, the coolant flowing in the outer area 19 collides with the separator 400a, and also the flow direction of the coolant is changed in the inner area 18 by the separator 400a. For example, as illustrated in FIG. 1, the coolant flowing in the clockwise direction in the outer area 19 flows in the counterclockwise direction in the inner area 18 by the separator 400a. As such, when the coolant collides with the separator 400a and the flow direction is changed, the flow speed of the coolant decreases and cooling efficiency is reduced. Furthermore, a coolant circulation speed may not be effectively controlled. Accordingly, it is desirable to maintain the flow direction of the coolant by configuring the separator of the cooling device like the separator 400b of FIG. 2.

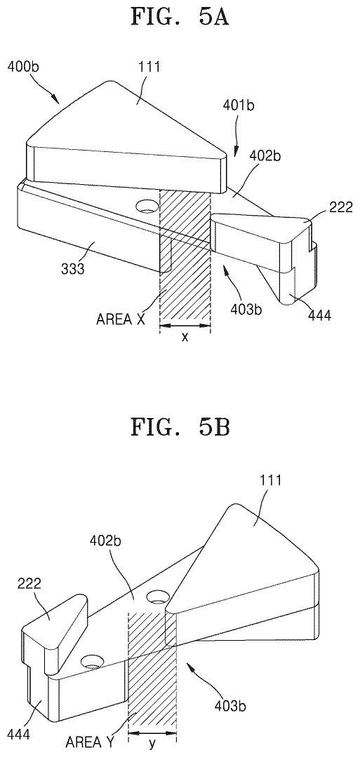

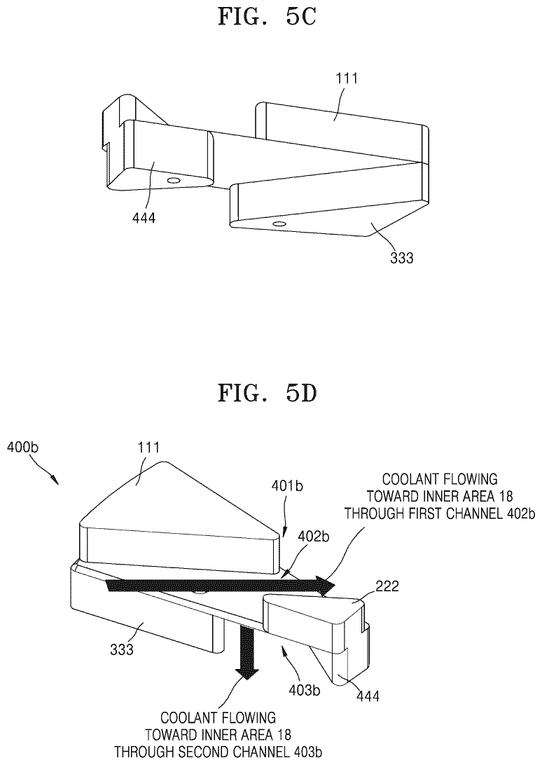

The structure of the separator 400b of FIG. 2 will be described in detail with reference to FIGS. 5A to 5D.

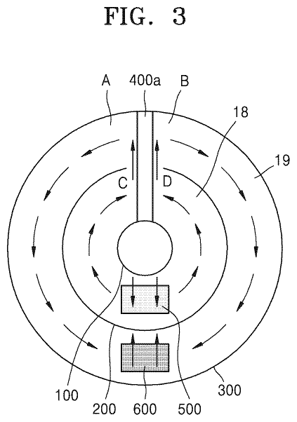

FIG. 3 is a schematic top view of a modified example of the cooling device of FIG. 1.

Unlike FIG. 1, in the cooling device of FIG. 3, the inlet 500 is arranged between the first partition 100 and the second partition 200, and the outlet 600 is arranged between the second partition 200 and the third partition 300.

Like FIG. 1, the separator 400a may connect the first area A and the third area C with each other and the second area B and the fourth area D with each other.

A coolant may be introduced into the inner area 18 of the fluid channel via the inlet 500. The introduced coolant is separated into two flows of the coolant flowing in different directions along the first partition 100 and the second partition 200. The two flows of the coolant may be introduced into the outer area 19 without colliding or mixing with each other due to the separator 400a. In detail, the coolant flowing in the third area C is introduced into the first area A by the separator 400a, and the coolant flowing in the fourth area D is introduced into the second area B by the separator 400a. The coolant introduced into the outer area 19 may be discharged through the outlet 600.

FIG. 4A is a perspective view of the separator 400a used in the cooling device of FIGS. 1 and 3, and FIG. 4B illustrates that the separator 400a of FIG. 4A is provided in the fluid channel.

The separator 400a may include a body 401a, a first channel 402a, and a second channel 403a.

The first channel 402a and the second channel 403a are located at opposite surfaces facing each other, that is, a left surface and a right surface, of the body 401a, and may be concave portions formed in the body 401a. The structures of the first channel 402a and the second channel 403a are not limited to the illustration of FIG. 4A. For example, although the first channel 402a and the second channel 403a are illustrated as concave portions having a flat surface, alternatively, they may be concave portions having a round surface.

Referring to FIG. 4B, the first area A and the third area C may be connected to each other via the first channel 402a of the separator 400a, and the second area B and the fourth area D may be connected to each other via the second channel 403a of the separator 400a.

The first channel 402a and the second channel 403a may not meet each other. Accordingly, the separator 400a may prevent the two flows of the coolant flowing in different directions from colliding with each other. In detail, in FIGS. 1 and 4B, the two flows of the coolant flowing in different directions in the outer area 19 may be introduced into the inner area 18 without colliding or mixing with each other due to the first channel 402a and the second channel 403a, and may flow in different directions in the inner area 18, and may be discharged through the outlet 600.

FIG. 4B illustrates that the coolant is introduced into the inner area 18 through the first channel 402a and the second channel 403a from the outer area 19.

The separator 400a may be arranged across the outer area 19 and the inner area 18. In the exemplified embodiment, the separator 400a extends from the third partition 300 to the first partition 100 by penetrating through the second partition 200. The body 401a, with the second partition 200, may prevent the coolant flows flowing in different directions from being mixed with each other.

FIGS. 5A to 5D are perspective views of the separator 400b used in the cooling device of FIG. 2, viewed from different directions. FIG. 5A is a perspective view of the separator 400b used in the cooling device of FIG. 2, viewed from the upper right side. FIG. 5B is a perspective view of the separator 400b used in the cooling device of FIG. 2, viewed from the upper left side. FIG. 5C is a perspective view of the separator 400b used in the cooling device of FIG. 2, viewed from the lower left side.

The separator 400b may include a body 401b, a first member 111, a second member 222, a third member 333, a fourth member 444, a first channel 402b, and a second channel 403b.

The first member 111 to the fourth member 444 may be separately manufactured and attached to the body 401b, or may be integrally formed with the body 401b.

The first channel 402b may be formed by the first member 111 and the second member 222. The second channel 403b may be formed by the third member 333 and the fourth member 444.

The first channel 402b is configured to connect the first area A and the third area C with each other, and the second channel 403b is configured to connect the second area B and the fourth area D with each other. In other words, the first area A and the third area C may be connected to each other by the first channel 402b of the separator 400b, and the second area B and the fourth area D may be connected to each other by the second channel 403b of the separator 400b.

The first channel 402b and the second channel 403b may not meet each other. For example, the first channel 402b and the second channel 403b may be located at opposite surfaces facing each other, that is, an upper surface and a lower surface, of the body 401b.

In detail, as illustrated, the first member 111 and the second member 222 are provided in an upper portion of the separator 400b. Accordingly, the first channel 402b may be formed in the upper portion of the separator 400b. The third member 333 and the fourth member 444 are provided in a lower portion of the separator 400b. Accordingly, the second channel 403b may be formed in the lower portion of the separator 400b. Thereby, the separator 400b may prevent the two flows of the coolant flowing in different directions from colliding with each other. The structures of the first channel 402b and the second channel 403b are not limited to the illustration of FIGS. 5A to 5D. For example, the first channel 402b and the second channel 403b may have an inclined structure.

Referring to FIGS. 2 and 5A-5D, one of the two flows of the coolant flowing in different directions in the outer area 19 may be introduced into the inner area 18 through the first channel 402b in the upper portion of the separator 400b, and the other coolant flow may be introduced into the inner area 18 through the second channel 403b in the lower portion of the separator 400b. In other words, the two flows of the coolant flowing in different directions in the outer area 19 may be introduced into the inner area 18 through the upper and lower portions of the separator 400b without colliding or mixing with each other, may also flow in different directions in the inner area 18, and may be discharged through the outlet 600. FIG. 5D illustrates that the coolant is introduced into the inner area 18 through the first channel 402b and the second channel 403b from the outer area 19.

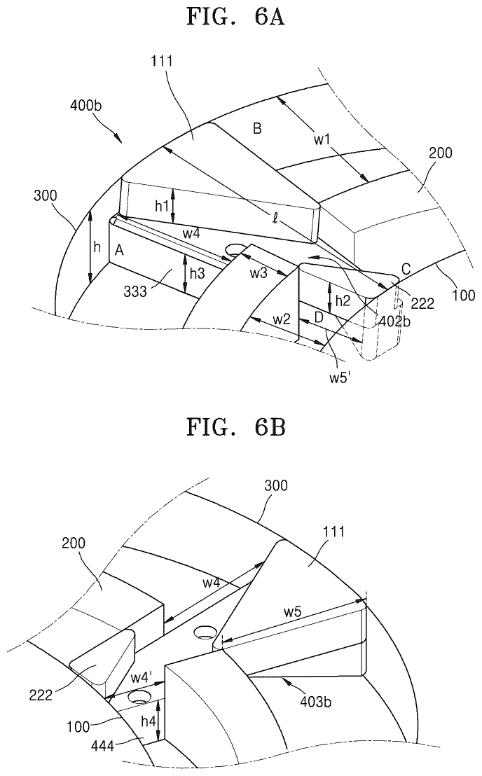

FIGS. 6A and 6B are perspective views of the separator 400b used in the cooling device of FIG. 2, showing a mutual arrangement relationship of the body 401b of the separator 400b, the first member 111, the second member 222, the third member 333, the fourth member 444, the first channel 402b, the second channel 403b, and the first to third partitions 100 to 300.

Referring to FIGS. 2, 6A and 6B, the body 401b may be arranged across the outer area 19 and the inner area 18. For example, the body 401b may extend from the third partition 300 to the first partition 100 by penetrating through the second partition 200.

The first member 111 formed in the upper portion of the separator 400b may be located between the second partition 200 and the third partition 300. The second member 222 formed in the upper portion of the separator 400b may be located between the first partition 100 and the second partition 200. The third member 333 formed in the lower portion of the separator 400b may be located between the second partition 200 and the third partition 300. The fourth member 444 formed in the lower portion of the separator 400b may be located between the first partition 100 and the second partition 200.

In order to prevent the coolant in the first area A from being mixed with the coolant flowing through the second channel 403b, and the coolant in the second area B from being mixed with the coolant flowing through the first channel 402b, an area between the second member 222 and the third member 333 (indicated by a reference letter X in FIG. 5A) and an area between the first member 111 and the fourth member 444 (indicated by a reference letter Y in FIG. 5B) should be blocked. To this end, the second partition 200 may be arranged to cover the area X and the area Y. To completely block the area X and the area Y, a width x of the area X and a width y of the area Y may be less than or equal to a thickness w3 of the second partition 200. In this case, one surface of each of the first member 111, the second member 222, the third member 333, and the fourth member 444 may come in contact with the second partition 200. In detail, the second partition 200 may contact one surface of the third member 333 in the first area A, one surface of the first member 111 in the second area B, one surface of the fourth member 444 in the third area C, and one surface of the second member 222 in the fourth area D. Accordingly, the separator 400b, with the second partition 200, may prevent the coolant flows flowing in different directions from being mixed with each other.

A length I of the separator 400b may be less than or equal to a distance between the first partition 100 and the third partition 300. In some embodiments, as illustrated in FIG. 6A, the length I of the separator 400b may be the same as the distance between the first partition 100 and the third partition 300. In this case, the first member 111 and the third member 333 may contact the third partition 300, and the second member 222 and the fourth member 444 may contact the first partition 100. Accordingly, the separator 400b, with the first partition 100 and the third partition 300, may prevent the coolant flows flowing in different directions in the inner area 18 and the outer area 19 from being mixed with each other. For example, the coolant flowing in the first area A may be prevented from flowing toward the second area B through the side surface of the separator 400b, and the coolant flowing in the third area C may be prevented from flowing toward the fourth area D.

The first member 111 and/or the second member 222 may contact a cover (not shown) of the cooling device. Accordingly, the separator 400b, with the cover of the cooling device, may prevent the coolant flows flowing in different direction in the inner area 18 and the outer area 19 from being mixed with each other. For example, the coolant flowing in the first area A may be prevented from flowing toward the second area B through the upper portion of the separator 400b, and the coolant flowing in the third area C may be prevented from flowing toward the fourth area D through the upper portion of the separator 400b.

A continuity equation for a fluid is shown as the following Equation 1, which may be induced from the law of conservation of mass. It may be seen from the continuity equation that a flow velocity decreases as a sectional area increases, and the flow velocity increases as the sectional area decreases.

$$Q = A 1 \times V 1 = A 2 \times V 2 , \qquad [ Equation 1 ]$$

where “Q” denotes a flow rate, “A1” denotes a sectional area at a first point, “V1” denotes a flow velocity at the first point, “A2” denotes a sectional area at a second point, and “V2” denotes a flow velocity at the second point.

In the embodiment of FIG. 6A, a distance w1 between the third partition 300 and the second partition 200 may be the same as a distance w2 between the second partition 200 and the first partition 100. The heights of the first partition 100, the second partition 200, and the third partition 300 may be the same as “h.” In this case, since a sectional area (w1×h) of the outer area 19 and a sectional area (w2×h) of the inner area 18 are the same, according to the continuity equation, a fluid velocity “vo” in the outer area 19 may be the same as a fluid velocity “vi” in the inner area 18 (∵vo/vi=(w2×h)/(w1×h)=1). Thus, an upper portion of a reactor may be cooled more uniformly.

In the embodiment of FIG. 6B, a height “h1” of the first member 111, a height “h2” of the second member 222, a height “h3” of the third member 333, and a height “h4” of the fourth member 444 may be the same. Furthermore, the first channel 402b may have a uniform width, that is, w4=w4′, and the second channel may have a uniform width, that is, w5=w5′. A width “w4” of the first channel 402b and a width “w5” of the second channel may be the same. In this case, according to the continuity equation for a fluid, a flow velocity “v1” of the coolant before passing through the separator 400b, that is, in the first area A and the second area B and a flow velocity “v2” of the coolant after passing through the separator 400b, that is, in the third area C and the fourth area D may be the same (∵v1/v2=(h2×w4′)/(h1×w4)=(h3×w5)/(h4×w5′)=1). Accordingly, a coolant circulation speed may be more easily controlled.

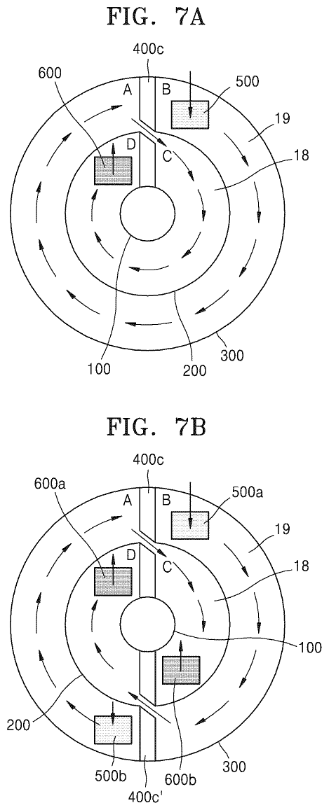

FIGS. 7A and 7B are schematic top views of a cooling device according to other embodiments. The cooling devices according to the present embodiments may be modifications of the cooling devices according to the above-described embodiments, and redundant descriptions between the embodiments are omitted.

Referring to FIG. 7A, the cooling device may include the first partition 100, the second partition 200 surrounding the first partition 100, the third partition 300 surrounding the second partition 200, a separator 400c, the inlet 500, and the outlet 600.

The separator 400c may separate the space between the second partition 200 and the third partition 300 into the first area A and the second area B, and the space between the second partition 200 and the first partition 100 into the third area C and the fourth area D. In the exemplified embodiment, the separator 400c is configured to extend between the third partition 300 and the first partition 100 by penetrating through the second partition 200.

Unlike the separator 400b of FIG. 2, the separator 400c may connect the first area A and the third area C with each other.

Due to the above configuration, the separator 400c of FIG. 7A may not change the direction of the coolant flowing along the fluid channel. For example, as illustrated in FIG. 7A, the coolant flowing in the clockwise direction in the outer area 19 is introduced into the third area C from the first area A by the separator 400c and also flows in the clockwise direction in the inner area 18. Thus, as the flow direction of the coolant is maintained, the coolant circulation speed may be maintained.

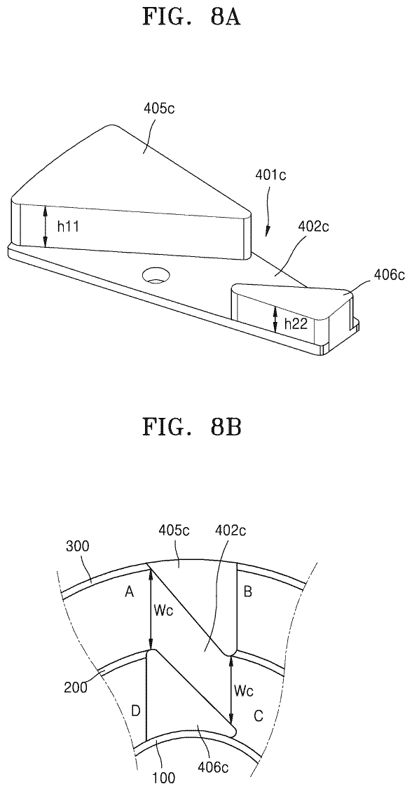

The structure of the separator 400c of FIG. 7A is described in detail with reference to FIGS. 8A and 8B.

FIG. 7B schematically illustrates a modified example of the cooling device of FIG. 7A.

Unlike FIG. 7A, the cooling device of FIG. 7B may include two inlets 500a and 500b, two outlets 600a and 600b, and two separators 400c and 400c′. As illustrated in FIG. 7B, two flows of the coolant introduced through the two inlets 500a and 500b may be introduced into the inner area 18 by the separators 400c and 400c′, without colliding or mixing with each other, and may be discharged through the two outlets 600a and 600b.

FIG. 8A is a perspective view of the separator 400c used for the cooling devices of FIGS. 7A and 7B. FIG. 8B illustrates that the separator 400c of FIGS. 7A and 7B is provided in the fluid channel. The separator 400c according to the present embodiment may be a modified example of the separators according to the above-described embodiments. Redundant descriptions between the embodiments are omitted.

The separator 400c may include a body 401c, a first member 405c, and a second member 406c. The first member 405c and the second member 406c may form a channel 402c.

The first member 405c and the second member 406c may be separately manufactured and attached to the body 401c, or may be integrally formed with the body 401c.

Referring to FIG. 8B, the first area A and the third area C may be connected through the channel 402c of the separator 400c.

The body 401c may be arranged across the outer area 19 and the inner area 18. In the exemplified embodiment, the body 401c may extend from the third partition 300 to the first partition 100 by penetrating through the second partition 200.

The first member 405c may be located between the second partition 200 and the third partition 300. The second member 406c may be located between the first partition 100 and the second partition 200.

In order to prevent the coolant flows flowing in different directions from being mixed with each other, for example, to prevent the coolant of the first area A from being mixed with the coolant of the fourth area D, and the coolant of the first area A from being mixed with the coolant of the second area B, one surface of each of the first member 405c and the second member 406c may come in contact with the second partition 200. In detail, as illustrated in FIG. 8B, the second partition 200 may contact one surface of the second member 406c in the fourth area D, and one surface of the first member 405c in the second area B. Accordingly, the separator 400c, with the second partition 200, may prevent the coolant flows flowing in different direction from being mixed with each other.

In some embodiments, a height h11 of the first member 405c and a height h22 of the second member 406c may be the same. Furthermore, the channel 402c may have a uniform width Wc. In this case, according to the continuity equation, the flow velocity “v1” of the coolant before passing through the separator 400c and the flow velocity “v2” of the coolant after passing through the separator 400c may be the same (∵v1/v2=(h22×Wc)/(h11×Wc)). Accordingly, the coolant circulation speed may be more easily controlled.

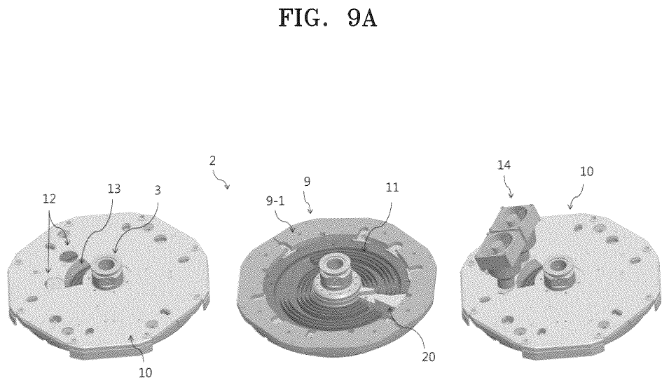

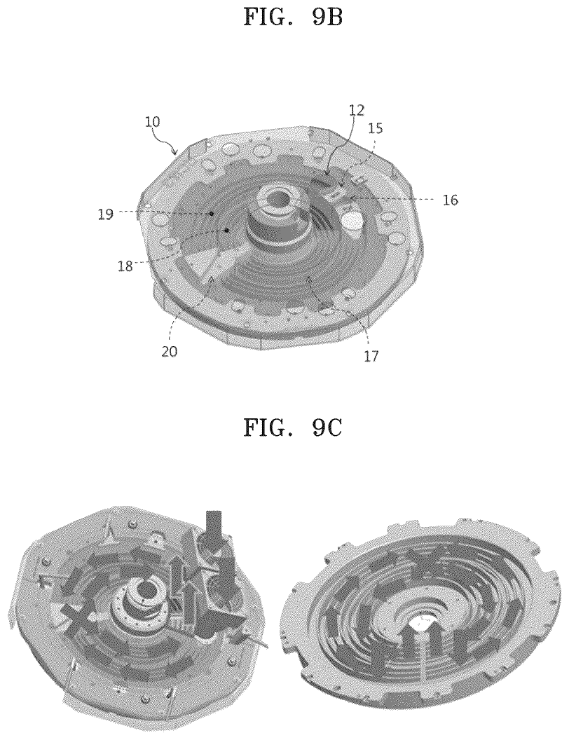

FIGS. 9A and 9B are, respectively, appearance and perspective views of a cooling device 2 according to another embodiment, and FIG. 9C illustrates a coolant flow path in the cooling device 2.

Referring to FIG. 9A, the cooling device 2 may include a fluid channel 9 through which the coolant flows and a cover 10 covering the fluid channel 9. The coolant may be a fluid, in particular, gas. A reaction gas inlet 3 may penetrate through the cooling device 2.

One or more circular grooves 11 may be arranged in the fluid channel 9 at a certain interval. The grooves 11 may define the flow direction of the coolant. Also, the one or more grooves 11 may increase a contact area between the coolant and the fluid channel 9, and thus an upper portion of a reactor 4, in particular, a gas supply device 5, may be more effectively cooled (see FIG. 16).

The cover 10 may include an inlet 12 for supplying a coolant, for example, air, to the fluid channel 9. The inlet 12 may be connected to a coolant input device 14. When the coolant in use is a gas, the coolant input device 14 may be a fan or a device corresponding thereto. In another embodiment, when a liquid coolant is in use, the coolant input device 14 may be a liquid supplier.

Furthermore, the cover 10 may include an outlet 13 configured to discharge the coolant. In this case, the coolant may be discharged through the outlet 13 after cooling the reactor 4 along the grooves 11 of the fluid channel 9. The outlet 13 may be connected to a coolant discharger (not shown). The coolant discharger may be a fan or a device corresponding thereto.

In a selective or additional example, a fan connected to the inlet 12 and a fan connected to the outlet 13, rotating in opposite directions, may further facilitate the flow of the coolant in the cooling device 2 and may effectively control the cooling efficiency. For example, while rotating in the opposite directions, the fan connected to the inlet 12 and the fan connected to the outlet 13 may make the flow of the coolant in the cooling device 2 a laminar flow. Accordingly, the cooling efficiency of the upper portion of the reactor may be more effectively controlled.

In a selective or additional example, the fan connected to the inlet 12 and the fan connected to the outlet 13, both having the same rotation speed, may further facilitate the flow of the coolant in the cooling device 2. Alternatively, by making the rotation speed of the fan connected to the outlet 13 faster than the rotation speed of the fan connected to the inlet 12, an outflow speed of the coolant supplied to the fluid channel 9 may be accelerated, and thus the cooling efficiency of the upper portion of the reactor may be further effectively controlled. Contrarily, by making the rotation speed of the fan connected to the outlet 13 slower than the rotation speed of the fan connected to the inlet 12, a time for the coolant staying in the fluid channel may be extended. Accordingly, the cooling efficiency may be controlled such that the temperature of the upper portion of the reactor is maintained constant.

The coolant input device 14 and the coolant discharger may be directly connected to the inlet 12 and the outlet 13, respectively. In another embodiment, the coolant input device 14 and the coolant discharger may be respectively spaced apart from the inlet 12 and the outlet 13 and may be connected by a coolant delivery line therebetween.

An insulation body 9-1 is further arranged over the fluid channel 9 and thus a danger that heat is transferred from the fluid channel 9 to a worker in a high temperature process may be prevented.

A separator 20 as described above or below may be arranged on one surface of the fluid channel 9. In the exemplified embodiment, the separator 20 may be the separator 400b illustrated in FIGS. 5A to 5D.

FIG. 9B is a perspective view of the cooling device 2 of FIG. 7A, showing the interior of the cooling device 2. According to FIG. 9B, the cover 10 of the cooling device 2 may include, on one surface thereof, at least one of a coolant guide plate 15, a first partition 16, and a second partition 17.

The coolant guide plate 15 may be configured to guide the coolant introduced through the inlet 12 to flow toward the grooves 11 of the fluid channel 9 and to define a direction in which the coolant flows in the fluid channel 9. Referring to FIG. 9C, it may be seen that the coolant is supplied to the fluid channel 9 to flow in different directions by the coolant guide plate 15. As described above, the coolant flows flowing in different directions may prevent the gas supply device 5 from being non-uniformly cooled.

The first partition 16 may be configured to prevent mixing of the coolants introduced in two directions. In the illustrated embodiment, the first partition 16 may be arranged between the two inlets 12 and may prevent the coolants introduced in two directions through the two inlets 12 from being mixed with each other.

The second partition 17 may separate the fluid channel 9 into two areas, that is, the inner area 18 and the outer area 19.

The separator 20 may be arranged on one surface of the fluid channel 9. In the exemplified embodiment, the separator 20 may be the separator 400b illustrated in FIGS. 5A to 5D. In this case, the coolant flowing along the grooves 11 in the outer area 19 of the fluid channel 9 may be guided to the inner area 18 by the separator 20. In particular, since the separator 20 is composed of two parts, upper and lower parts, as illustrated in FIGS. 5A-5D, the two flows of the coolant flowing in different directions in the outer area 19 may be introduced into the inner area 18 without colliding with each other.

The coolant flowing in the inner area 18 along the grooves 11 may be discharged to the outside through the outlet 13.

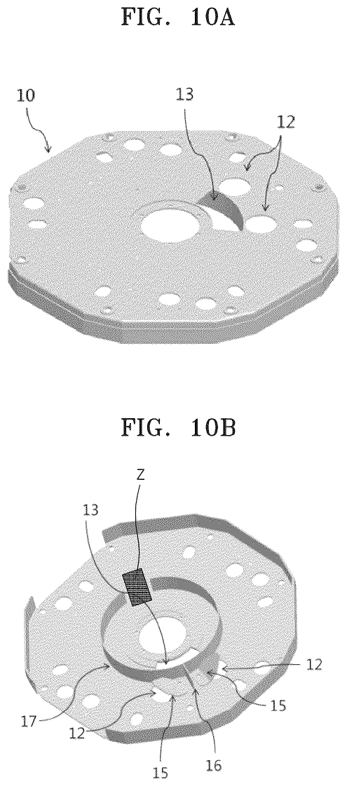

FIGS. 10A and 10B schematically illustrate the cover 10 of the cooling device 2 of FIG. 9A. FIG. 10A is a front side view of the cover 10, and FIG. 10B is a rear side view of the cover 10.

Referring to FIGS. 10A and 10B, the cover 10 may include the inlet 12, the outlet 13, the coolant guide plate 15, the first partition 16, and the second partition 17.

Although FIGS. 10A and 10B illustrate that two inlets and one outlet are respectively arranged as the inlet 12 and the outlet 13, the present disclosure is not limited thereto. For example, one inlet and two outlets may be respectively arranged as the inlet 12 and the outlet 13.

The coolant guide plate 15 is arranged around the inlet 12 to guide the coolant introduced through the inlet 12 to flow toward the fluid channel 9, and may be configured to define the direction in which the coolant flows in the fluid channel 9.

As described above, the first partition 16 may be arranged between the two inlets 12 and may prevent the coolants introduced in two directions through the two inlets 12 from being mixed with each other.

As illustrated in FIG. 10B, the second partition 17 may form an empty space Z to allow the separator 20 to extend across the inner area 18 and the outer area 19.

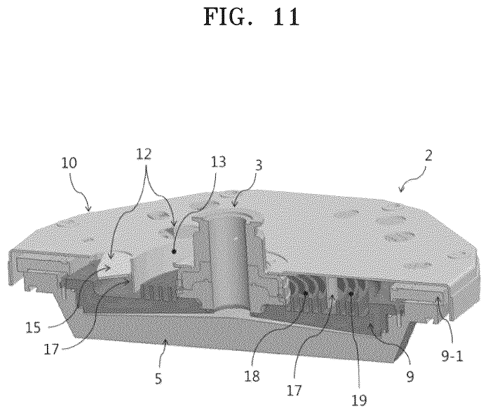

FIG. 11 is a cross-sectional view of the gas supply device 5 including the cooling device 2 of FIG. 9C. Referring to FIG. 11, it may be seen that the fluid channel 9 is separated into the inner area 18 and the outer area 19 by the second partition 17 of the cover 10 of the cooling device 2.

The cooling device 2 may be provided over the gas supply device 5. Since detailed descriptions about each part of the cooling device 2 of FIG. 11 are already presented above in relation to FIG. 9A, FIGS. 10A and 10B, the descriptions are omitted.

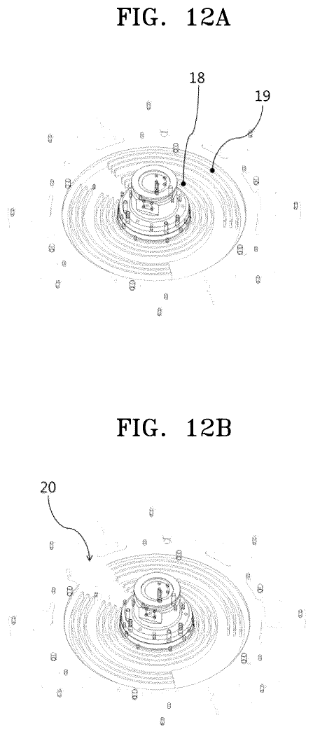

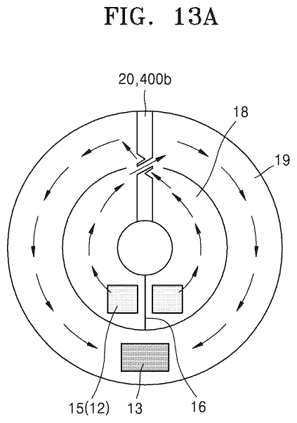

FIGS. 12A and 12B are perspective views of the cooling device 2 of FIG. 11 before being covered with a cover. FIG. 12A illustrates the cooling device 2 before the separator 20 is provided. FIG. 12B illustrates that the separator 20 is provided in the fluid channel 9.

Referring to FIGS. 12A and 12B, one or more circular grooves are arranged in the fluid channel 9 at a certain interval. Since the detailed descriptions about each part of the cooling device 2 of FIGS. 12A and 12B are already presented above in relation to FIG. 9A and FIGS. 10A and 10B, the descriptions are omitted.

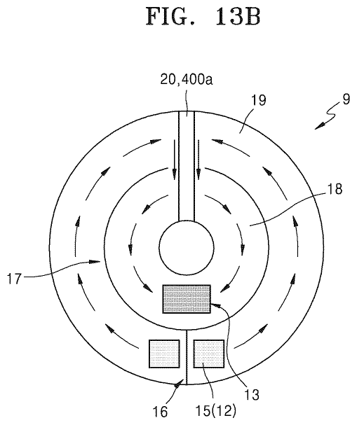

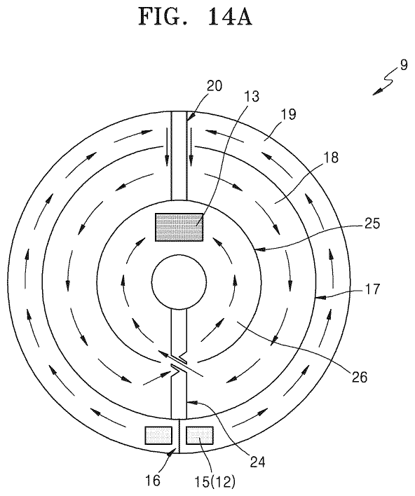

According to other embodiments of the present disclosure, considering cooling efficiency and non-uniform temperature distribution, the number and arrangement form of the coolant guide plate, the partition, the separator, the inlet, the outlet, etc. may be diversified, and thus the cooling efficiency may be improved. In this regard, detailed descriptions are provided with reference to FIGS. 13A to 15B.

FIGS. 13A and 13B are schematic top views illustrating various flow directions of the coolant flowing in the cooling device, according to embodiments. According to FIGS. 13A and 13B, various coolant flows may be implemented by changing the number and/or arrangement form of the coolant, the coolant guide plate 15, the first partition 16, the separator 20, the inlet 12, and the outlet 13.

As a first example, the cooling device 2 may include the separator 400b of FIGS. 5A to 5D, as illustrated in FIG. 13A. In the example, the coolant is first introduced into the inner area 18 of the fluid channel 9 through the two inlets 12. The coolant flows in different directions along the groove of the inner area 18 by the coolant guide plate 15 and/or the first partition 16. The coolant flowing in the clockwise direction in the inner area 18 flows in the clockwise direction in the outer area 19 by passing through the second channel 403b of the separator 400b (see FIG. 5A). The coolant flowing in the counterclockwise direction in the inner area 18 flows in the counterclockwise direction in the outer area 19 by passing through the first channel 402b of the separator 400b. The coolant flows flowing in different directions in the outer area 19 are discharged through the outlet 13. According to the present example, the cooling unbalance between the left side and the right side of the gas supply device may be prevented, and temperature uniformity may be guaranteed. Furthermore, as described above, since the flow direction of the coolant is not changed due to the separator 400b, the flow speed of the coolant may not be decreased. Accordingly, coolant circulation may be effectively controlled.

As a second example, the cooling device 2 may include the separator 400a of FIGS. 4A and 4B or a partition-type separator, as illustrated in FIG. 13B. In the example, the coolant is first introduced into the outer area 19 of the fluid channel 9 through the two inlets 12. The coolant flows in different directions along the groove of the outer area 19 by the coolant guide plate 15 and/or the first partition 16. The coolant flowing in the outer area 19 is discharged through the outlet 13 after flowing along the groove of the inner area 18 by the separator 400a (see FIGS. 4A and 4B).

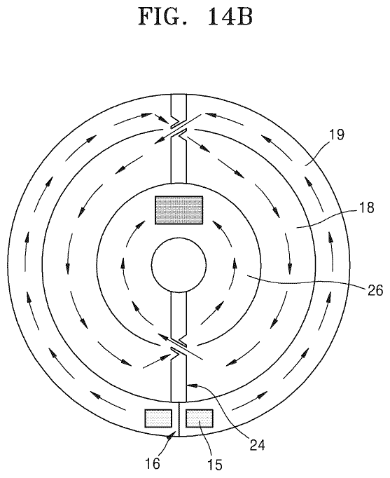

FIGS. 14A and 14B are schematic top views of cooling devices according to other embodiments. The cooling devices according to these embodiments may be modifications of the cooling devices according to the above-described embodiments. Redundant descriptions between the embodiments are omitted.

Referring to FIGS. 14A and 14B, the cooling device may include the first partition 16, the second partition 17, a third partition 25, the first separator 20, and a second separator 24. The third partition 25 may be arranged between the second partition 17 and the reaction gas inlet 3 and may separate the fluid channel 9 into the first inner area 18 and a second inner area 26.

The coolant is first introduced into the outer area 19 of the fluid channel 9 through the inlet 12. The coolant flows in different directions along the groove of the outer area 19 by the coolant guide plate 15 and/or the first partition 16. The coolant flows flowing in the opposite directions in the outer area 19 are guided to flow toward the first inner area 18 by the first separator 20 without colliding with each other. The coolant flows introduced into the first inner area 18 and flowing in the opposite directions are guided to flow toward the second inner area 26 by the second separator 24 without colliding with each other, and then are discharged through the outlet 13.

Since the cooling devices of FIGS. 14A and 14B further include the third partition 25 and the second separator 24 compared to the above-described cooling devices, the coolant may be circulated one more time in the fluid channel 9, and thus the upper portion of the reactor may be more uniformly cooled.

As it may be seen from FIGS. 14A and 14B, by changing the number and/or arrangement form of the separator 20 and the partition, various coolant flows may be implemented. Accordingly, cooling efficiency of the upper portion of the reactor in a high temperature process may be further improved.

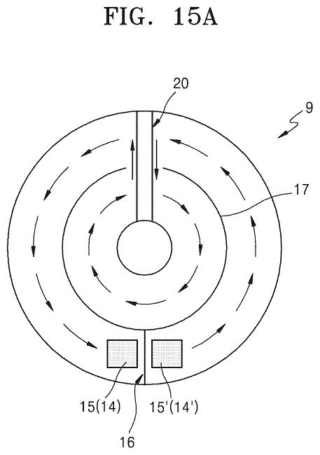

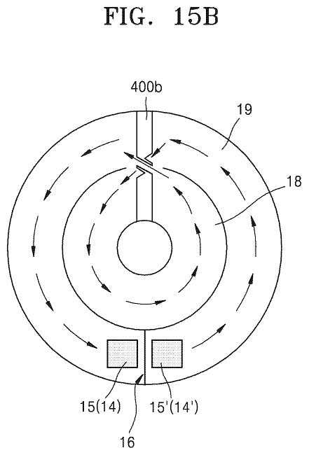

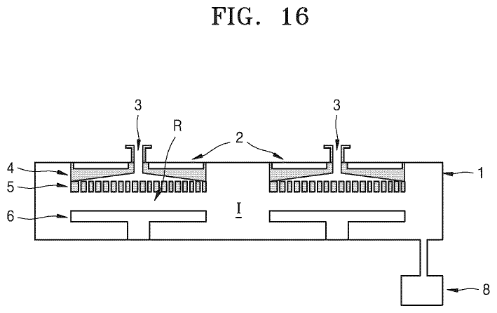

FIGS. 15A and 15B are schematic top views of cooling devices, according to other embodiments. The cooling devices according to these embodiments may be modifications of the cooling devices according to the above-described embodiments. Redundant descriptions between the embodiments are omitted.

The cooling devices of FIGS. 15a and 15B may circulate the coolant with only inlets 15 and 15′ and the coolant input devices 14 and 14′, without the outlet 13 and the coolant discharger connected to the outlet 13. In detail, instead of the outlet 13 that is not provided, by changing the rotation directions of the two coolant input devices 14 and 14′, for example, the rotation direction of the fan, opposite to each other, the coolant may be circulated in the outer area 19 and the inner area 18. In other words, the coolant may be introduced by using one of the two fans and discharged through the other fan, thereby cooling the upper portion of the reactor. In a selective or additional example, the upper portion of the reactor may be cooled by periodically changing the rotation directions of the two fans (cycling cooling). The present embodiment may be identically applied to the above-described cooling devices.

FIG. 16 is a schematic cross-sectional view of a substrate processing apparatus including the cooling device, according to another embodiment. An example of the substrate processing apparatus described in the present specification may include a deposition apparatus of a semiconductor or display substrate, but the present disclosure is not limited thereto. The substrate processing apparatus may be any apparatus needed for performing deposition of a material for forming a thin film, or may refer to an apparatus for uniformly supplying a material for etching to polishing of an object. In the following description, for convenience of explanation, the substrate processing apparatus is assumed to be a semiconductor deposition apparatus.

The substrate processing apparatus according to an embodiment may include a chamber 1, a plurality of reactors 4, the gas supply device 5, a substrate support 6, the reaction gas inlet 3, the cooling device 2, and a discharge device 8. In FIG. 16, the chamber 1 may include a top lid arranged in an upper portion of the chamber 1, an outer wall forming a side surface and a lower surface of the chamber 1, and an inner space I between the top lid and the outer wall.

Referring to FIG. 16, the reactors 4 are provided on the upper surface of the chamber 1. The reactors 4 may perform an atomic layer deposition (ALD) or a chemical vapor deposition (CVD), for example.

The substrate support 6 may be arranged corresponding to the gas supply device 5, and may be configured to form a reaction space R with the gas supply device 5. When the substrate support 6 and the gas supply device 5 form the reaction space R that is an open type, without contacting each other, a reaction gas may be discharged through the discharge device 8 connected to the inner space I. The inner space I may maintain a pressure state lower than the outside atmosphere due to the discharge device 8. The discharge device 8 may be, for example, a discharge pump. In the exemplified embodiment, the substrate processing apparatus has a lower-end discharge structure, but the present disclosure is not limited thereto.

Although FIG. 16 illustrates each of the reactors 4 that is an open type in which the substrate support 6 and the gas supply device 5 are separated from each other, in another embodiment, as the substrate support 6 or a reactor wall ascends or descends, a peripheral portion of the substrate support 6 and the reactor wall have face contact and face sealing, thereby forming the reaction space R. As such, when the reactor wall and the reactor wall contact each other forming a closed-type reaction space, a separate discharge device (not shown) may be provided in each of the reactors 4, for example, in the upper portion of each reactor 4. Korean Patent No. 624030 discloses one embodiment thereof.

The gas supply device 5 may be arranged on the top lid of the chamber 1 facing the substrate support 6 in the reaction space R of each reactor 4. The gas supply device 5 may be implemented, for example, in a lateral flow type assembly structure (see Korean Patent No. 624030) or a shower head type assembly structure. The cooling device 2 may be provided over each of the reactors 4 or over the gas supply device 5. In the exemplified embodiment, the cooling device 2 may be one of the above-described cooling devices. The cooling device 2 may be separately manufactured and arranged over each of the reactors 4 or the gas supply device 5, or the cooling device 2 may be integrally formed with each of the reactors 4 or with the gas supply device 5.

The reaction gas inlet 3 may be arranged over each of the reactors 4. For example, the reaction gas inlet 3 may be connected to the gas supply device 5 of each reactor 4 and may introduce a reaction gas into the reaction space R. In the exemplified embodiment, the reaction gas inlet 3 is connected to the gas supply device 5 by penetrating through the cooling device 2.

A high frequency plasma generation/supply apparatus (not shown) is additionally arranged over each of the reactors 4 to generate plasma in the reaction space R or supply radicals to the reaction space R so that a plasma process may be performed in the reaction space R.

To summarize some of the configurations, the substrate processing apparatus according to an embodiment may be described as follows.
The substrate processing apparatus may include the cooling device capable of controlling the temperature of the upper portion of the reactor, in detail, the gas supply device, for example, a shower head.
The cooling device may include the separator configured to uniformly and efficiently cool the gas supply device.
The separator enables two flows of the coolant to circulate along the fluid channel 9 without colliding or mixing with each other. Since the coolant flows are not mixed with each other, a coolant circulation speed may be maintained and thus cooling efficiency may be improved.
The separators of FIGS. 5A to 5D and FIGS. 8A and 8B prevent mixing of different coolant flows and simultaneously enable the coolant flow to circulate along the fluid channel 9 while maintaining the flow direction of the coolant. Accordingly, a coolant circulation speed may be maintained in the fluid channel 9, and the coolant circulation speed may be easily controlled by using the coolant input device.
Cooling efficiency may be improved by diversifying the number and/or arrangement form of the coolant guide plate, the partition, the separator, etc. of the cooling device according to the embodiments of the present disclosure.
According to the present disclosure, the temperature of the gas supply device may be maintained constant. Accordingly, stability during a maintenance and repair work may be reinforced and reproducibility of a process may be improved. Furthermore, malfunction of parts of the reactor at high temperature may be prevented.

The above disclosure provides a plurality of embodiments of the substrate processing apparatus including the cooling device, and representative merits thereof. For brevity, only a limited number of combinations of related features have been described. However, it is understood that the features of any example can be combined with the features of any other example. Moreover, it is to be understood that these advantages are non-limiting and that particular advantages are not, or need not be, features of any particular embodiment.

In order to clearly understand the present disclosure, the shape of each part of the accompanying drawings is to be understood as being illustrative. It should be noted that the present disclosure can be modified into various shapes other than the shapes shown.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A cooling device comprising:
a first partition;
a second partition surrounding the first partition;
a third partition surrounding the second partition; and
a separator separating a space between the second partition and the third partition into a first area and a second area, and separating a space between the second partition and the first partition into a third area and a fourth area,
wherein the separator is configured to connect the first area and the third area with each other and/or the second area and the fourth area with each other.

2. The cooling device of claim 1, wherein the separator comprises a body, a first channel, and a second channel,
the first area and the third area are connected to each other by the first channel of the separator,
the second area and the fourth area are connected to each other by the second channel of the separator, and
the first channel and the second channel do not meet each other.

3. The cooling device of claim 2, wherein the first channel is in an upper portion of the separator, and
the second channel is in a lower portion of the separator.

4. The cooling device of claim 1, wherein the cooling device further comprises an inlet for introducing a coolant, and,
when the inlet is located between the second partition and the third partition,
the separator enables the coolant flowing in a clockwise direction between the second partition and the third partition to continue to flow in a clockwise direction between the first partition and the second partition, and
the separator enables the coolant flowing in a counterclockwise direction between the second partition and the third partition to continue to flow in a counterclockwise direction between the first partition and the second partition, and
when the inlet is located between the first partition and the second partition,
the separator enables the coolant flowing in a clockwise direction between the first partition and the second partition to continue to flow in a clockwise direction between the second partition and the third partition, and
the separator enables the coolant flowing in a counterclockwise direction between the first partition and the second partition to continue to flow in a counterclockwise direction between the second partition and the third partition.

5. The cooling device of claim 1, further comprising one or more grooves arranged between the first partition and the second partition or between the second partition and the third partition.

6. A cooling device comprising:
a fluid channel through which a coolant circulates, the coolant being introduced through at least one inlet;
a partition separating the fluid channel into a first area and a second area; and
a separator penetrating through the partition and extending across the first area and the second area,
wherein the at least one inlet introduces the coolant into the first area,
wherein two flows of the coolant flowing in different directions are formed in the first area, and
wherein the two flows of the coolant flowing in different directions in the first area are introduced into the second area via the separator without colliding or mixing with each other.

7. The cooling device of claim 6, wherein the separator enables the coolant flowing in a clockwise direction in the first area to continue to flow in a clockwise direction in the second area, and
the separator enables the coolant flowing in a counterclockwise direction in the first area to continue to flow in a counterclockwise direction in the second area.

8. A cooling device comprising:
a first partition;
a second partition surrounding the first partition;
a third partition surrounding the second partition; and
a separator separating a space between the second partition and the third partition into a first area and a second area, and separating a space between the second partition and the first partition into a third area and a fourth area,
wherein the separator is configured to connect the first area and the third area with each other.

9. The cooling device of claim 8, wherein the separator comprises a body and a channel, and
the first area and the third area are connected to each other by the channel of the separator.

10. The cooling device of claim 8, wherein the separator comprises:
a body;
a first member located between the second partition and the third partition;
a second member located between the first partition and the second partition; and
a channel formed by the first member and the second member,
wherein the first area and the third area are connected to each other by the channel.

11. The cooling device of claim 10, wherein one surface of each of the first member and the second member contacts the second partition.

12. The cooling device of claim 10, wherein the first member contacts the third partition, and
the second member contacts the first partition.

13. The cooling device of claim 10, wherein the first member and the second member have a same height, and
the channel has a uniform width.

14. The cooling device of claim 8, wherein, when a flow direction of the coolant in the first area is a clockwise direction, the separator enables the coolant flowing in a clockwise direction in the first area to continue to flow in a clockwise direction in the third area, and
when a flow direction of the coolant in the first area is a counterclockwise direction, the separator enables the coolant flowing in a counterclockwise direction in the first area to continue to flow in a counterclockwise direction in the third area.

15. A substrate processing apparatus comprising:
a chamber having an inner space surrounded by a top lid and an outer wall;
at least one reactor located in the top lid and comprising a gas supply device;
at least one substrate support located on a wall of the chamber and facing the reactor;
a reaction space formed between the reactor and the substrate support; and
a cooling device as set forth in claim 1.
